(19) United States
(12) Patent Application Publication
(10) Pub. No.: US 2015/0183960 A1
(43) Pub. Date: Jul. 2, 2015

(54) Reactive Silicone Composition, Reactive Thermoplastic Article, Cured Product, And Optical Semiconductor Device

(71) Applicant: Dow Corning Toray Co., Ltd., Tokyo (JP)

(72) Inventors: Ryosuke Yamazaki, Ichihara-shi (JP); Haruna Yamazaki, Ichihara-shi (JP); Makoto Yoshitake, Ichihara-shi (JP)

(73) Assignee: Dow Corning Toray Co., Ltd., Tokyo (JP)

(21) Appl. No.: 14/407,093

(22) PCT Filed: Jun. 18, 2013
(86) PCT No.: PCT/JP2013/067163

§ 371 Date: Dec. 11, 2014

(30) Foreign Application Priority Data
Jun. 29, 2012 (JP) 2012-148037

(51) Int. Cl. C08K 7/18; H01L 33/60; C08K 3/22; C08K 7/14; C08K 3/36

(52) U.S. Cl. CPC C08K 7/18; C08K 7/14; C08K 3/36; C08K 3/22; H01L 33/60; C08K 2003/2241

(57) ABSTRACT

The present invention relates to a reactive silicone composition comprising: (A) an alkenyl group-containing organopolysiloxane represented by the average unit formula; (B) an alkenyl group-containing organopolysiloxane represented by the general formula; (C) a silicon atom-bonded hydrogen atom-containing organopolysiloxane represented by the general formula; (D) a hydrosilylation reaction catalyst; (E) a white pigment; and (F) non-spherical silica, spherical silica or glass fibers, a reactive thermoplastic article obtained by the composition to reaction under specified conditions, a cured product obtained by heating the article, and an optical semiconductor device having the cured product. The reactive silicone composition is a solid at an ordinary temperature and gives a reactive thermoplastic article that is fluidized at elevated temperatures. The reactive thermoplastic article is once fluidized upon heating and then gives a cured product. The cured product exhibits little reduction in mechanical strength or discoloration caused by heat or light and has high light reflectance. And the optical semiconductor device exhibits high luminous efficiency and causes little thermal degradation or photodegradation of a light reflection material.

### TECHNICAL FIELD

The present invention relates to a reactive silicone composition, a reactive thermoplastic article, a cured product, and an optical semiconductor device.

Priority is claimed on Japanese Patent Application No. 2012-148037, filed on Jun. 29, 2012, the content of which is incorporated herein by reference.

### BACKGROUND ART

Curable silicone compositions that cure by a hydrosilylation reaction are used as protective agents, coating agents, lens-molding materials, light reflection materials, or the like for optical semiconductor elements in optical semiconductor devices such as photocouplers, light emitting diodes, and solid-state image sensing-devices. Among theses, the compositions used as light reflection materials can be exemplified by a resin composition for a mounting package that incorporates an optical semiconductor element, where this resin composition comprises a thermosetting type addition reactive silicone resin that has a structure in which vinyl groups and/or allyl groups, and hydrogen atoms are directly bonded to silicon atoms, a platinum-type catalyst as a curing catalyst, and a white pigment (refer to Japanese Unexamined Patent Application Publication No. 2009-021394); and by an addition reaction cure type silicone resin composition that cures to form a cured body with an average visible light reflectance of at least 80% and that comprises a vinyl group-containing organopolysiloxane with a weight average molecular weight (Mw) of at least 30,000, an organohydrogenpolysiloxane having at least two silicon atom-bonded hydrogen atoms in a molecule, a white pigment, an inorganic filler other than the white pigment, a platinum metallic catalyst, and a reaction control agent (refer to Japanese Unexamined Patent Application Publication No. 2011-140550).

These compositions have had problems in transfer molding, injection molding, or compression molding in that there is low mold filling, voids and burrs are readily generated, and mold release performance is poor. These compositions have further problems due to slow cure rate and poor workability in the molding procedure. Moreover, although cured products obtained by curing these compositions have dvantage of little discoloration due to heat and light, the cured products have problems of high linear expansion coefficients, and low mechanical strength at high temperature. There have also been problems in that light reflectance is insufficient, and there is a large decrease in mechanical strength due to heat and light.

An object of the present invention is to provide a reactive silicone composition which is substantially a solid at an ordinary temperature and which gives a reactive thermoplastic article that is fluidized at elevated temperatures, a reactive thermoplastic article which is once fluidized upon heating and then gives a cured product, a cured product which exhibits little reduction in mechanical strength or discoloration caused by heat or light and has high light reflectance, and an optical semiconductor device which exhibits high luminous efficiency and causes little thermal degradation or photodegradation of a light reflection material.

### DISCLOSURE OF INVENTION

The reactive silicone composition of the present invention comprises:

(A) 100 parts by mass of an organopolysiloxane represented by the average unit formula:

(R¹₃SiO_{1/2})ₐ(R¹₂SiO_{2/2})_{b}(R¹SiO_{3/2})_{c}(SiO_{4/2})_{d}(R²O_{1/2})ₑ

wherein R¹ are the same or different and are phenyl groups, alkyl groups having from 1 to 6 carbon atoms, or alkenyl groups having from 2 to 6 carbon atoms, provided that from 55 to 80 mol % of all R¹ are phenyl groups and from 10 to 20 mol % of all R¹ are alkenyl groups; R² is a hydrogen atom or an alkyl group having from 1 to 6 carbon atoms; and “a”, “b”, “c”, “d”, and “e” are numbers that respectively satisfy: 0≦a≦0.30, 0.10≦b≦0.70, 0.35≦c≦0.85, 0≦d≦0.20, 0≦e≦0.10, and a+b+c+d=1;
(B) from 0 to 40 parts by mass of an organopolysiloxane represented by the general formula:

R³₃SiO(R³₂SiO)ₙSiR³₃

wherein R³ are the same or different and are phenyl groups, alkyl groups having from 1 to 6 carbon atoms, or alkenyl groups having from 2 to 6 carbon atoms, provided that from 30 to 70 mol % of all R³ are phenyl groups and at least one R³ is an alkenyl group; and “n” is an integer in a range from 10 to 100;
(C) an organopolysiloxane represented by the general formula:

HR⁴₂SiO(R⁴₂SiO)ₘSiR⁴₂H

wherein R⁴ are the same or different and are phenyl groups or alkyl groups having from 1 to 6 carbon atoms, provided that from 15 to 100 mol % of all R⁴ are phenyl groups; and “m” is an integer in a range from 1 to 10,
in an amount that provides from 0.5 to 2.5 moles of silicon atom-bonded hydrogen atoms in this component per 1 mol of total alkenyl groups in components (A) and (B);
(D) a hydrosilylation reaction catalyst in an amount sufficient to promote a hydrosilylation reaction between the alkenyl groups in components (A) and (B) and the silicon atom-bonded hydrogen atoms in component (C);
(E) a white pigment in an amount of at least 50 parts by mass per 100 parts by mass of the total amount of components (A) to (D); and
(F) non-spherical silica, spherical silica or glass fibers in an amount of at least 100 parts by mass per 100 parts by mass of the total amount of components (A) to (D), the total content of components (E) and (F) being not more than 400 parts by mass per 100 parts by mass of the total amount of components (A) to (D).

In addition, the reactive thermoplastic article of the present invention is obtained by subjecting the above-mentioned reactive silicone composition to hydrosilylation reaction until the degree of conversion is from 70 to 95%.

Furthermore, the cured product of the present invention is obtained by heating the above-mentioned reactive thermoplastic article at a temperature of 100° C. or higher and is a solid or a liquid with a viscosity at least 1,000,000 Pa·s at 300° C.

Furthermore, the optical semiconductor device of the present invention comprises a light reflection material formed from the above-mentioned cured product.

### Effects of Invention

The reactive silicone composition of the present invention gives a reactive thermoplastic article which is substantially a solid at an ordinary temperature and which is fluidized at elevated temperatures. In addition, the reactive thermoplastic article of the present invention is once fluidized upon heating and then giving a cured product, and is suitable for forming a cured product in a heated mold. Moreover, the cured product of the present invention has little discoloration or lowering of mechanical strength due to heat or light and has high light reflectance. Furthermore, the optical semiconductor device of the present invention exhibits high luminous efficiency and causes little thermal degradation or photodegradation of a light reflection material.

### BRIEF DESCRIPTION OF THE DRAWINGS

FIG. 1 is a cross-sectional drawing of an LED as one example of an optical semiconductor device of the present invention.

### DETAILED DESCRIPTION OF THE INVENTION

First, the reactive silicone composition of the present invention will be described in detail.

Component (A) is a main component of the present composition and is an organopolysiloxane represented by the average unit formula:

(R¹₃SiO_{1/2})ₐ(R¹₂SiO_{2/2})_{b}(R¹SiO_{3/2})_{c}(SiO_{4/2})_{d}(R²O_{1/2})ₑ

In the formula, R¹ are the same or different and are phenyl groups, alkyl groups having from 1 to 6 carbon atoms, or alkenyl groups having from 2 to 6 carbon atoms. Examples of the alkyl group for R¹ include methyl groups, ethyl groups, propyl groups, butyl groups, pentyl groups, hexyl groups, cyclopentyl groups, and cyclohexyl groups. Examples of the alkenyl group for R¹ include vinyl groups, allyl groups, butenyl groups, pentenyl groups, and hexenyl groups. Note that among all R¹, the content of the phenyl groups is in a range from 55 to 80 mol %, and preferably is in a range from 60 to 75 mol %. When the content of the phenyl groups is greater than or equal to the lower limit of the aforementioned range, the hardness at room temperature and fluid characteristics at elevated temperatures of the obtained reactive thermoplastic article are good, and mechanical strength of the obtained cured product is good. On the other hand, when the content of the phenyl groups is less than or equal to the aforementioned upper limit, the hardness of the obtained cured product at elevated temperatures is good. Moreover, the content of the alkenyl groups in all R¹ in the formula is in a range from 10 to 20 mol %. When the content of the alkenyl groups is greater than or equal to the lower limit of the aforementioned range, hardness of the obtained cured product at room temperature is good. On the other hand, when the content of the alkenyl groups is less than or equal to the upper limit of the aforementioned range, mechanical strength of the obtained cured product is good.

Moreover, R² in the formula is a hydrogen atom or an alkyl group having from 1 to 6 carbon atoms. Examples of the alkyl group for R² include methyl groups, ethyl groups, propyl groups, butyl groups, pentyl groups, and hexyl groups.

Moreover, in the formula, “a” is a number indicating the fraction of siloxane units represented by the general formula: R¹₃SiO_{1/2}, and “a” is a number satisfying 0≦a≦0.30, and preferably 0≦a≦0.25. When the value of “a” is less than or equal to the aforementioned upper limit, hardness of the obtained cured product at room temperature is good. Moreover, “b” is a number indicating the fraction of siloxane units represented by the general formula: R¹₂SiO_{2/2}, and “b” is a number satisfying 0.10≦b≦0.70, and preferably 0.15≦b≦0.60. When the value of “b” is greater than or equal to the lower limit of the aforementioned range, the hardness at room temperature and fluid characteristics at elevated temperatures of the obtained reactive thermoplastic article are good, and when the value of “b” is less than or equal to the aforementioned upper limit, the hardness of the obtained cured product at room temperature is good. Moreover, “c” is a number indicating the fraction of siloxane units represented by the general formula: R¹SiO_{3/2}, and “c” is a number satisfying 0.35≦c≦0.85, and preferably 0.40≦c≦0.80. When the value of “c” is greater than or equal to the lower limit of the aforementioned range, the hardness of the obtained cured product at room temperature is good. On the other hand, when the value of “c” is less than or equal to the upper limit of the aforementioned range, mechanical strength of the obtained cured product is good. Moreover, “d” is a number indicating the fraction of siloxane units represented by the general formula: SiO_{4/2}, and “d” is a number satisfying 0≦d≦0.20, and preferably 0≦d≦0.10. When the value of “d” is less than or equal to the upper limit of the aforementioned range, mechanical strength of the obtained cured product is good. Moreover, “e” is a number indicating the fraction of units represented by the general formula: R²O_{1/2}, and “e” is a number satisfying 0≦e≦0.10. When the value of “e” is less than or equal to the aforementioned upper limit, hardness of the obtained cured product at room temperature is good. Furthermore, the sum of “a”, “b”, “c”, and “d” in the formula is 1.

Component (A) generally has a molecular weight distribution and is a mixture of a plurality of organopolysiloxanes. In addition, component (A) may be obtained by blending individually prepared organopolysiloxanes. In such cases, each organopolysiloxane need not correspond to the average unit formula specified above, and the mixture thereof may satisfy the above-mentioned average unit formula.

Component (B) is an optional component for adjusting viscosity of the present composition and for adjusting hardness and mechanical strength of the obtained cured product. Component (B) is an organopolysiloxane represented by the general formula:

R³₃SiO(R³₂SiO)ₙSiR³₃

In the formula, R³ are the same or different and are phenyl groups, alkyl groups having from 1 to 6 carbon atoms, or alkenyl groups having from 2 to 6 carbon atoms. Examples of the alkyl group for R³ include methyl groups, ethyl groups, propyl groups, butyl groups, pentyl groups, hexyl groups, cyclopentyl groups, and cyclohexyl groups. Examples of the alkenyl group for R³ include vinyl groups, allyl groups, butenyl groups, pentenyl groups, and hexenyl groups. In the formula, among all R³, the content of the phenyl groups is in a range from 30 to 70 mol %, and preferably is in a range from 40 to 60 mol %. When the content of the phenyl groups is greater than or equal to the lower limit of the aforementioned range, mechanical strength of the obtained cured product is good. On the other hand, when the content of the phenyl groups is less than or equal to the aforementioned upper limit, hardness of the obtained cured product is good. Moreover, at least one R³ is an alkenyl group. This component participates in the curing reaction when component (B) has an alkenyl group.

In the formula, “n” is an integer in a range from 10 to 100, and preferably is an integer in a range from 10 to 50. When “n” is greater than or equal to the lower limit of the aforementioned range, mechanical strength of the obtained cured product is good. On the other hand, when “n” is less than or equal to the upper limit of the aforementioned range, handling and processability of the obtained cured product is good.

The content of component (B) in the present composition, per 100 parts by mass of component (A), is in a range from 0 to 40 parts by mass, and preferably is in a range from 0 to 20 parts by mass. When the content of component (B) is less than or equal to the aforementioned upper limit, hardness of the obtained cured product is good.

Component (C) is a crosslinking agent of the present composition and is an organopolysiloxane represented by the general formula:

HR⁴₂SiO(R⁴₂SiO)ₘSiR⁴₂H

In the formula, R⁴ are the same or different and are phenyl groups or alkyl groups having from 1 to 6 carbon atoms. Examples of the alkyl group for R⁴ include methyl groups, ethyl groups, propyl groups, butyl groups, pentyl groups, hexyl groups, cyclopentyl groups, and cyclohexyl groups. In the formula, among all R⁴, the content of the phenyl groups is in a range from 15 to 100 mol %, and preferably is in a range from 30 to 100 mol %. When the content of the phenyl groups is greater than or equal to the lower limit of the aforementioned range, the hardness at room temperature and fluid characteristics at elevated temperatures of the obtained reactive thermoplastic article are good, and mechanical strength of the obtained cured product is good. On the other hand, when the content of the phenyl groups is less than or equal to the aforementioned upper limit, the hardness of the obtained cured product is good.

In the formula, “m” is an integer in a range from 1 to 10, and preferably is an integer in a range from 1 to 5. When “m” is greater than or equal to the lower limit of the aforementioned range, mechanical strength of the obtained cured product is good. On the other hand, when “m” is less than or equal to the upper limit of the aforementioned range, handling and processability of the obtained cured product is good.

The content of component (C) in the present composition, per 1 mol of total alkenyl groups in components (A) and (B), is in a range such that the silicon atom-bonded hydrogen atoms in component (C) is in a range from 0.5 to 2.0 mol, and preferably in a range from 0.5 to 1.5 mol. When the content of component (C) is within the aforementioned range, hardness of the obtained cured product is good.

Component (D) is a hydrosilylation reaction catalyst for promoting hydrosilylation reaction between the alkenyl groups in components (A) and (B) and the silicon atom-bonded hydrogen atoms in component (C). Examples of component (D) include platinum-based catalysts, rhodium-based catalysts, and palladium-based catalysts. Platinum-based catalysts are preferred due to the ability to remarkably promote curing of the present composition. Examples of the platinum-based catalysts include platinum fine powder, chloroplatinic acid, alcoholic solutions of chloroplatinic acid, platinum-alkenylsiloxane complexes, platinum-olefin complexes, and platinum-carbonyl complexes. Platinum-alkenylsiloxane complexes are particularly preferred. Examples of the alkenylsiloxane include 1,3-divinyl-1,1,3,3-tetramethyldisiloxane, 1,3,5,7-tetramethyl-1,3,5,7-tetravinylcyclotetrasiloxane, alkenylsiloxanes having part of the methyl groups of these alkenylsiloxane substituted by ethyl groups, phenyl groups, or the like, and alkenylsiloxanes having vinyl groups of these alkenylsiloxanes substituted by allyl groups, hexenyl groups, or the like. 1,3-divinyl-1,1,3,3-tetramethyldisiloxane is particularly preferred due to high stability of the platinum-alkenylsiloxane complex. Due to the ability for improving the stability of the platinum-alkenylsiloxane complexes, combination is recommended of the platinum-alkenylsiloxane complexes with alkenylsiloxanes such as 1,3-divinyl-1,1,3,3-tetramethyldisiloxane, 1,3-diallyl-1,1,3,3-tetramethyldisiloxane, 1,3-divinyl-1,3-dimethyl-1,3-diphenyldisiloxane, 1,3-divinyl-1,1,3,3-tetraphenyldisiloxane, and 1,3,5,7-tetramethyl-1,3,5,7-tetravinylcyclotetrasiloxane or organosiloxane oligomers such as dimethylsiloxane oligomers. The addition of alkenylsiloxanes is particularly preferred.

No particular limitation is placed on the content of component (D) in the present composition as long as there is an amount sufficient to promote hydrosilylation reaction between the alkenyl groups in components (A) and (B) and the silicon atom-bonded hydrogen atoms in component (C). However, this concentration in the present composition, based on the metal atoms in component (D), is preferably from 0.01 to 500 ppm, further preferably is from 0.01 to 100 ppm, and particularly preferably is from 0.01 to 50 ppm in terms of mass units. When the content of component (D) is greater than or equal to the lower limit of the aforementioned range, hardness of the obtained composition is good. On the other hand, when the content of component (D) is less than or equal to the upper limit of the aforementioned range, the obtained cured product is resistant to discoloration.

Component (E) is a white pigment for coloring the composition of the present invention and cured product thereof white and for increasing light reflectance. Preferred examples of component (E) include metal oxides such as titanium oxide, alumina, zinc oxide, zirconium oxide, and magnesium oxide; barium sulfate, zinc sulfate, or the like; and titanium oxide and zinc oxide are particularly preferred.

Although no particular limitation is placed on the shape and the average particle diameter of component (E), the average particle diameter is preferably in a range from 0.05 to 10.0 μm, and particularly preferably is in a range from 0.1 to 5.0 μm. In order to increase the compatibility and dispersibility of the white pigment with the resin and inorganic filler, the white pigment may be surface-treated using a silane coupling agent, silica, alumina, or the like.

The content of component (E) in the present composition, per 100 parts by mass of total amount of components (A) to (D), is at least 50 parts by mass, and preferably is at least 60 parts by mass. When the content of component (E) is greater than or equal to the lower limit of the aforementioned range, light reflectance of the cured product is good.

Component (F) is spherical silica, non-spherical silica or glass fibers, and is used to ameliorate a deterioration in workability caused by an increase in viscosity of the composition of the present invention, reduce the linear expansion coefficient of the cured product and improve dimensional stability. Examples of the spherical silica for component (F) include dry-method silica, wet-method silica, fused silica and deflagration method silica, but fused silica is preferred due to exhibiting good filling properties in the present composition. Examples of the non-spherical silica for component (F) include quartz powder and glass beads, but quartz powder is preferred. Examples of the glass fibers for component (F) include chopped glass fibers and milled glass fibers, but milled glass fibers are preferred.

The particle diameter of the spherical silica for component (F) is not limited, but the average particle diameter is preferably from 0.1 to 50 μm, and especially from 0.5 to 20 μm. The average particle diameter of the non-spherical silica for component (F) is not limited, but is preferably from 0.1 to 20 μm, and particularly preferably from 0.5 to 10 μm. The shape of the glass fibers for component (F) is not limited, but the diameter of the fibers is preferably from 1 to 50 μm, and particularly preferably from 5 to 20 μm, and the length of the fibers is preferably from 5 to 500 μm, and particularly preferably from 10 to 300 μm.

The content of component (F) in the present composition, per 100 parts by mass of total amount of components (A) to (D), is at least 100 parts by mass, and preferably is at least 120 parts by mass. When the content of component (G) is greater than or equal to the lower limit of the aforementioned range, linear expansion coefficient of the obtained cured product is low and dimensional stability is good.

The total content of components (E) and (F) in the present composition, per 100 parts by mass of total amount of components (A) to (D), is not more than 400 parts by mass, and preferably is not more than 350 parts by mass. When the total content of components (E) and (F) is less than or equal to the aforementioned upper limit, viscosity of the obtained composition is good.

The present composition preferably contains, as an adhesion promoter for increasing adhesion to a substrate that is in contact during curing, (G) an organopolysiloxane represented by the average unit formula:

(R⁵₃SiO_{1/2})_{f}(R⁵₂SiO_{2/2})_{g}(R⁵SiO_{3/2})ₕ(SiO_{4/2})ᵢ(R⁶O_{1/2})ⱼ

In the formula, R⁵ are the same or different and are phenyl groups, alkyl groups having from 1 to 6 carbon atoms, alkenyl groups having from 2 to 6 carbon atoms, or epoxy group-containing organic groups. Examples of the alkyl group for R⁵ include methyl groups, ethyl groups, propyl groups, butyl groups, pentyl groups, heptyl groups, cyclopentyl groups, and cycloheptyl groups. Examples of the alkenyl group for R⁵ include vinyl groups, allyl groups, butenyl groups, pentenyl groups, and hexenyl groups. Examples of the epoxy group-containing organic group for R⁵ include 3-glycidoxypropyl groups, 4-glycidoxybutyl groups, 2-(3,4-epoxycyclohexyl) ethyl groups, and 3-(3,4-epoxycyclohexyl)propyl groups. In the formula, among all R⁵, the content of the phenyl groups is in a range from 15 to 60 mol %, and preferably is in a range from 20 to 50 mol %. When the content of the phenyl groups is greater than or equal to the lower limit of the aforementioned range, adhesion and reflectance of the obtained cured product is good. When the content of the phenyl groups is less than or equal to the aforementioned upper limit, adhesion and heat resistance properties of the obtained cured product is good. In the formula, among all R⁵, the content of the alkenyl groups is in a range from 3 to 30 mol %, and preferably is in a range from 5 to 20 mol %. When the content of the alkenyl groups is within the aforementioned range, adhesion of the obtained cured product is good. Also, among all of R⁵, the content of the epoxy group-containing organic groups is in a range from 5 to 30 mol %, and preferably is in a range from 10 to 20 mol %. When the content of the epoxy group-containing organic groups is greater than or equal to the lower limit of the aforementioned range, adhesion of the obtained cured product is good. When the content of the epoxy group-containing organic groups is less than or equal to the aforementioned upper limit, heat resistance properties is good.

Moreover, R⁶ in the formula is a hydrogen atom or an alkyl group having from 1 to 6 carbon atoms. Examples of the alkyl group of R⁶ include methyl groups, ethyl groups, butyl groups, pentyl groups, and hexyl groups.

Moreover, in the formula, “f” is a number indicating the fraction of siloxane units represented by the general formula: R⁵₃SiO_{1/2}, and “f” is a number satisfying 0≦f≦0.5, and preferably 0≦f≦0.4. When the value of “f” is less than or equal to the upper limit of the aforementioned range, adhesion of the obtained cured product is good. Moreover, in the formula, “g” is a number indicating the fraction of siloxane units represented by the general formula: R⁵₂SiO_{2/2}, and “g” is a number satisfying 0≦g≦0.9, and preferably 0≦g≦0.8. When the value of “g” is less than or equal to the upper limit of the aforementioned range, adhesion of the obtained cured product is good. Moreover, “h” is a number indicating the fraction of siloxane units represented by the general formula: R⁵SiO_{3/2}, and “h” is a number satisfying 0≦h≦0.7, and preferably 0≦h≦0.6. When the value of “h” is less than or equal to the upper limit of the aforementioned range, adhesion of the obtained cured product is good. Moreover, “i” is a number indicating the fraction of siloxane units represented by the general formula: SiO_{4/2}, and “i” is a number satisfying 0≦i≦0.3, and preferably 0≦i≦0.2. When the value of “i” is less than or equal to the upper limit of the aforementioned range, adhesion of the obtained cured product is good. Moreover, “j” is a number indicating the fraction of units represented by the general formula: R⁶O_{1/2}, and “j” is a number satisfying 0≦j≦0.02. When the value of “j” is less than or equal to the upper limit of the aforementioned range, storage stability and usable life of the present composition are good. Furthermore, the sum of “f”, “g”, “h”, and “i” in the formula is 1.

The content of component (G) in the present composition, per 100 parts by mass of total amount of components (A) to (D), is preferably in a range from 0.5 to 10.0 parts by mass, and particularly preferably is in a range from 1.0 to 8.0 parts by mass. When the content of component (G) is less than or equal to the upper limit of the aforementioned range, heat resistance properties of the obtained cured product is good. When the content of component (G) is greater than or equal to the lower limit of the aforementioned range, adhesion of the obtained cured product is good.

It is preferable for the present composition to contain a second crosslinking agent that is (H) an organopolysiloxane, which has two or more silicon atom-bonded hydrogen atoms in a molecule and in which the content of phenyl groups relative to all of the silicon atom-bonded organic groups is less than 20 mol %, in order to extend the usable life at normal temperature without impairing the curability of the present composition and in order to increase adhesion of a sealing material for an optical semiconductor device to a cured product of the present composition.

The number of the silicon atom-bonded hydrogen atoms in a molecule in component (H) is greater than or equal to 2. If this number of the silicon atom-bonded hydrogen atoms is present, crosslinking for curing is sufficient, and hardness of the obtained cured product is good. Examples of the silicon-bonded organic groups in component (H) include monovalent hydrocarbon groups having no unsaturated aliphatic bond, as exemplified by methyl groups, ethyl groups, propyl groups, butyl groups, pentyl groups, hexyl groups, heptyl groups, cyclopentyl groups, cyclohexyl groups, cycloheptyl groups, or similar alkyl groups; phenyl groups, tolyl groups, xylyl groups, or similar aryl groups; and benzyl groups, phenethyl groups, or similar aralkyl groups. Of these, phenyl groups and alkyl groups having from 1 to 6 carbon atoms are preferred. The content of the phenyl group relative to all of the silicon atom-bonded organic groups in component (H) is less than 20 mol %, and preferably is not more than 10 mol %. Preferably, at least 90 mol % of all of the silicon atom-bonded organic groups in component (H) are methyl groups. When the content of the phenyl groups is less than the aforementioned upper limit and when the content of the methyl groups is greater than or equal to the lower limit of the aforementioned range, adhesion of the obtained cured product toward various types of substrates is good, and adhesion of the sealing material used for an optical semiconductor device to the cured product is good.

Examples of component (H) include an organopolysiloxane represented by the formula:

(MeHSiO)ₚ

(in the formula, “Me” is a methyl group, and “p” is an integer in a range from 4 to 8) and organopolysiloxanes represented by the general formulae:

Me₃SiO(MeHSiO)_{q}SiMe₃

Me₃SiO(MeHSiO)ᵣ(Me₂SiO)ₛSiMe₃

(in the formulae, “Me” is a methyl group; “q” is an integer greater than or equal to 5; “r” and “s” are respective integers greater than or equal to 5; and “r” is equal to or greater than “s”).

The content of component (H) in the present composition, per 1 mol of total alkenyl groups in components (A) and (B), is in a range such that the silicon atom-bonded hydrogen atoms in component (H) is in a range from 0.001 to 0.20 mol, and preferably in a range from 0.002 to 0.10 mol. When the content of component (H) is within the aforementioned range, the usable life of the composition at normal temperatures is extended, adhesion of a sealing material for an optical semiconductor device to the obtained cured product is good, and the fluidity at elevated temperatures of a reactive thermoplastic article obtained by subjecting the present composition to hydrosilylation reaction is good.

Although the aforementioned components (A) to (F) are essential components of the present composition, other optional components include a reaction control agent such as 1-ethynyl-1-cyclohexanol, 2-methyl-3-butyn-2-ol, 3,5-dimethyl-1-hexyn-3-ol, 2-phenyl-3-butyn-2-ol, or similar alkyne alcohols; 3-methyl-3-penten-1-yne, 3,5-dimethyl-3-hexen-1-yne, or similar eneyne compounds; and 1,3,5,7-tetramethyl-1,3,5,7-tetravinylcyclotetrasiloxane, 1,3,5,7-tetramethyl-1,3,5,7-tetrahexenylcyclotetrasiloxane, and benzotriazole. Although no limitation is placed on the content of this reaction control agent, this content in the present composition is preferably in a range from 1 to 5,000 ppm in terms of mass units.

The present composition may contain an adhesion promoter other than the above-mentioned component (G). The adhesion promoter is exemplified by: organosilanes or organosiloxane oligomers having about 4 to 20 silicon atoms and a straight, branched, or cyclic structure in either case that contain a trialkoxysiloxy group (e.g., trimethoxysiloxy group or triethoxysiloxy group) or a trialkoxysilylalkyl group (e.g., trimethoxysilylethyl group or triethoxysilylethyl group) and a hydrosilyl group or an alkenyl group (e.g., a vinyl group or an allyl group); organosilanes or organosiloxane oligomers having about from 4 to 20 silicon atoms and a straight, branched, or cyclic structure in either case that contain a trialkoxysiloxy group or trialkoxysilylalkyl group and a methacryloxyalkyl group (e.g., 3-methacryloxypropyl group); organosilanes or organosiloxane oligomers having about 4 to 20 silicon atoms and a straight, branched, or cyclic structure in either case that contain a trialkoxysiloxy group or trialkoxysilylalkyl group and an epoxy group-bonded alkyl group (e.g., 3-glycidoxypropyl group, 4-glycidoxybutyl group, 2-(3,4-epoxycyclohexyl)ethyl group, or 3-(3,4-epoxycyclohexyl)propyl group); and reactants between aminoalkyltrialkoxysilanes and epoxy group-bonded alkyltrialkoxysilanes, and epoxy group-containing ethyl polysilicate. Specific examples of the adhesion promoter include: vinyltrimethoxysilane, allyltrimethoxysilane, allyltriethoxysilane, hydrogentriethoxysilane, 3-glycidoxypropyltrimethoxysilane, 3-glycidoxypropyltriethoxysilane, 2-(3,4-epoxycyclohexyl)ethyl trimethoxysilane, 3-methacryloxypropyltrimethoxysilane, 3-methacryloxypropyltriethoxysilane, reactants between 3-glycidoxypropyltriethoxysilane and 3-aminopropyl triethoxysilane, condensation reaction products between silanol group-chain terminated methylvinylsiloxane oligomers and 3-glycidoxypropyl trimethoxysilane, condensation reaction products between silanol group-chain terminated methylvinylsiloxane oligomers and 3-methacryloxypropyltriethoxysilane, and tris(3-trimethoxysilylpropyl) isocyanurate.

Furthermore, as long as the object of the present invention is not impaired, other optional components may be contained in the present composition. Such other optional components include inorganic fillers other than the spherical silica, non-spherical silica and glass fibers; fine powders of organic resins such as polymethacrylate resins and silicone resins; mold release agents such as carnauba wax, higher fatty acids, metal salts of higher fatty acid and methyl silicone oils; heat-resistant agents; flame retardants; and solvents.

Although no particular limitation is placed on the viscosity of the present composition at 25° C., the viscosity is preferably at least 10,000 Pas, and particularly preferably is in a range from 10 to 5,000 Pas. When the viscosity is greater than or equal to the lower limit of the above-mentioned range, it is easy to form a reactive thermoplastic article having the desired shape. On the other hand, when the viscosity is less than or equal to the upper limit of the above-mentioned range, and the handling and processability of the obtained composition is good.

Next, the reactive thermoplastic article of the present invention will be described in detail.

The reactive thermoplastic article of the present invention is obtained by subjecting the above-mentioned reactive silicone cured product to hydrosilylation reaction until the degree of conversion is from 70 to 95%. The degree of conversion in the hydrosilylation expresses, as a percentage, the proportion of functional groups that actually reacted relative to the total quantity of functional groups involved in the hydrosilylation reaction, and the method for confirming the degree of conversion is not particularly limited, but can be, for example, a method of measuring the quantity of heat generated in the reactive silicone composition and the quantity of heat generated in the obtained reactive thermoplastic article using differential scanning calorimetry (DSC) and simply calculating the degree of conversion from this difference. The reaction progresses either at room temperature or under heating, but carrying out the reaction under heating is preferable in order to efficiently obtain a reactive thermoplastic article. Heating temperature is preferably in a range from 50 to 150° C., and further preferably is in a range from 80 to 130° C.

The reactive thermoplastic article of the present invention is preferably a solid or a liquid with a viscosity of at least 1,000,000 Pa·s at 25° C. and a liquid with a viscosity of not more than 100,000 Pa·s at 100° C.

In addition, the reactive thermoplastic article of the present invention preferably has a type D durometer hardness at 25° C., as stipulated in JIS K 7215-1986 “Test methods for durometer hardness of plastics”, of at least 30.

This type of reactive thermoplastic article of the present invention is once fluidized by being heated at a temperature of 100° C. or higher and then undergoes a hydrosilylation reaction to give a cured product.

The cured product of the present invention will be described next in detail.

The cured product of the present invention is obtained by heating the above-mentioned reactive thermoplastic article so as to carry out the remainder of the hydrosilylation reaction, and is a solid or a liquid with a viscosity of at least 1,000,000 Pa·s at 300° C. Although no particular limitation is placed on the hardness of the cured product, the type D durometer hardness as stipulated in JIS K 7215-1986 “Testing Methods for Durometer Hardness of Plastics” is preferably at least 60, further preferably is at least 65, and particularly preferably is at least 70. When hardness is greater than or equal to the lower limit of the aforementioned range, dimensional stability of the cured product improves and resistance to deformation of the cured product increases.

Although no particular limitation is placed on reflectance of the cured product, total luminous reflectance as measured according to the method stipulated in JIS K 7375: 2008 “Plastics—Determination of Total Luminous Transmittance and Reflectance” is preferably at least 80%, and particularly preferably is at least 90%.

Although no particular limitation is placed on the linear expansion coefficient of the cured product, the linear expansion coefficient measured according to the method stipulated in JIS K 7197-1991 “Testing Method for Linear Thermal Expansion Coefficient of Plastics by Thermomechanical Analysis” in the temperature range of from 25 to 200° C. has an average value that is preferably not more than 200 ppm/° C., and particularly preferably is not more than 150 ppm/° C.

In addition, the cured product of the present invention is preferably obtained by curing the reactive thermoplastic article in a metal mold heated at a temperature of 100° C. or higher. In cases where the present cured product is formed as a reflective material for an optical semiconductor device, the curing method is preferably compression molding or transfer molding.

The optical semiconductor device of the present invention will be described next in detail.

The optical semiconductor device of the present invention is characterized in that a light reflection material is formed from the above-mentioned cured product. This type of optical semiconductor device is exemplified by a light emitting diode (LED). The light reflection material in this optical semiconductor device functions as a packaging material of the optical semiconductor device.

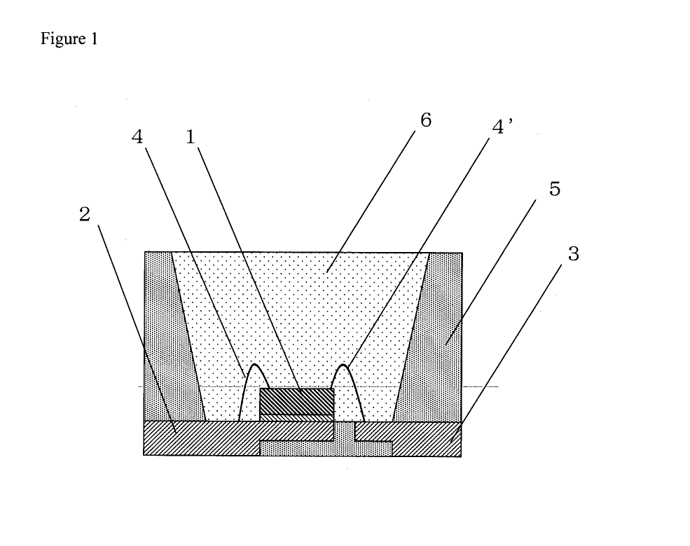

FIG. 1 illustrates a cross-sectional drawing of a surface mounted type LED, which is one example of the semiconductor device of the present invention. In the LED illustrated in FIG. 1, an optical semiconductor element 1 is die bonded to a lead frame 2 by a die bonding material, and this optical semiconductor element 1 are further wire bonded to lead frames 2,3 by bonding wires 4,4′. At the periphery of this optical semiconductor element 1, with the exception of the upper part thereof, a light reflection material 5 composed of the cured product is present. The optical semiconductor element 1 within this light reflection material 5 is sealed by the sealing agent 6.

The method of production of the surface mounted type LED illustrated in FIG. 1 is exemplified by a method including the steps of: (1) forming a light reflection material 5 integrated with the lead frames 2,3 by compression molding or transfer molding of the reactive thermoplastic article of the present invention, (2) die bonding the optical semiconductor element 1 on the lead frame 2 using a die bonding material, (3) wire bonding the optical semiconductor element 1 and the lead frames 2,3 using the bonding wires 4,4′, and (4) sealing the optical semiconductor element 1 using the sealing agent 6.

### EXAMPLES

The curable silicone composition, reactive thermoplastic article, cured product and optical semiconductor device of the present invention will now be described using Practical Examples and Comparative Examples. Moreover, in the formulae, Me, Ph, Vi, and Ep respectively represent methyl group, phenyl group, vinyl group, and 3-glycidoxypropyl group.

In addition, the hardness of the reactive thermoplastic article and the cured product were measured by a type D durometer as stipulated in JIS K 7215-1986 “Testing Methods for Durometer Hardness of Plastics”.

Bending strength of the cured product was measured according to the method stipulated in JIS K 6911-1995 “General Testing Methods of Thermosetting Plastics”.

Total luminous reflectance of the cured product was measured by the method stipulated in JIS K 7375:2008 “Plastics—Determination of Total Luminous Transmittance and Reflectance.”

Average linear expansion coefficient of the cured product in the temperature range of from 25 to 200° C. was measured by the method stipulated in JIS K 7197-1991 “Testing Method for Linear Thermal Expansion Coefficient of Plastics by Thermomechanical Analysis”.

In addition, the degree of conversion in the hydrosilylation reaction is obtained by determining the quantity of reaction heat in each state by means of differential scanning calorimetry, and then calculating the degree of conversion from this difference.

### Practical Example 1

100 parts by mass of methylvinylphenylpolysiloxane represented by the average unit formula:

(MeViSiO_{2/2})_{0.25}(Ph₂SiO_{2/2})_{0.30}(PhSiO_{3/2})_{0.45}(HO_{1/2})_{0.02}

13.3 parts by mass of dimethylvinylsiloxy-terminated polymethylphenylsiloxane represented by the average formula:

ViMe₂SiO(MePhSiO)_{17.5}SiViMe₂

33.3 parts by mass of 1,1,5,5-tetramethyl-3,3-diphenyltrisiloxane represented by the formula:

(HMe₂SiO)₂SiPh₂

(in an amount that provided 1.15 moles of silicon atom-bonded hydrogen atoms in this component per 1 mol of total vinyl groups in the above-mentioned methylvinylphenylpolysiloxane and dimethylvinylsiloxy-terminated polymethylphenylsiloxane), a 1,3-divinyl-1,1,3,3-tetramethyldisiloxane solution of a platinum-1,3-divinyl-1,1,3,3-tetramethyldisiloxane complex (used in the composition in such an amount that in terms of mass units the content of the metallic platinum in this complex was 5.0 ppm), 1-ethynyl-1-cyclohexanol (used in the composition in such an amount that in terms of mass units the content of this component was 300 ppm), 122 parts by mass of titanium oxide having an average primary particle diameter of 0.2 μm (SX-3103 manufactured by Sakai Chemical Industry Co., Ltd.) and 220 parts by mass of a crushed quartz powder having an average particle diameter of 5 μm (Crystalite VX-52 manufactured by Tatsumori Ltd.) were mixed so as to prepare a reactive silicone composition having a viscosity of 410 Pa·s at 25° C.

It was understood that when this composition was heated for 10 minutes at 120° C., the composition gave a thermoplastic article which was a solid having an unmeasurable viscosity and a type D durometer hardness of 65 at 25° C. and which had a viscosity of 650 Pa·s at 100° C. The degree of conversion in the hydrosilylation reaction was 87%.

When heated at 150° C., the obtained thermoplastic article fluidized and then lost fluidity. A cured product obtained by heating the thermoplastic article for 1 hour at 150° C. was a solid having an unmeasurable viscosity at 300° C., had a type D durometer hardness of 85 at 25° C., had a bending strength of 17 MPa, had a total luminous reflectance of 94% and had a cured product linear expansion coefficient of 110 ppm/° C.

A transfer molding machine and the above-mentioned thermoplastic article were used to produce the optical semiconductor device illustrated in FIG. 1. A good molded product free of burrs and voids was obtained by integrating molding with a lead frame at 130° C.

### Practical Example 2

48.4 parts by mass of methylvinylphenylpolysiloxane represented by the average unit formula:

(MeViSiO_{2/2})_{0.25}(Ph₂SiO_{2/2})_{0.30}(PhSiO_{3/2})_{0.45}(HO_{1/2})_{0.02}

51.6 parts by mass of methylvinylphenylpolysiloxane represented by the average unit formula:

(Me₂ViSiO_{1/2})_{0.20}(PhSiO_{3/2})_{0.80}(HO_{1/2})_{0.01}

0.02 parts by mass of epoxy group-containing polysiloxane represented by the average unit formula:

(Me₂ViSiO_{1/2})_{0.2}(MeEpSiO_{2/2})_{0.25}(PhSiO_{3/2})_{0.55}(HO_{1/2})_{0.005}

12.9 parts by mass of dimethylvinylsiloxy-terminated polymethylphenylsiloxane represented by the average formula:

ViMe₂SiO(MePhSiO)_{17.5}SiViMe₂

29.0 parts by mass of 1,1,5,5-tetramethyl-3,3-diphenyltrisiloxane represented by the formula:

(HMe₂SiO)₂SiPh₂

(in an amount that provided 0.96 moles of silicon atom-bonded hydrogen atoms in this component per 1 mol of total vinyl groups in the above-mentioned methylvinylphenylpolysiloxanes and dimethylvinylsiloxy-terminated polymethylphenylsiloxane), a 1,3-divinyl-1,1,3,3-tetramethyldisiloxane solution of a platinum-1,3-divinyl-1,1,3,3-tetramethyldisiloxane complex (used in the composition in such an amount that in terms of mass units the content of the metallic platinum in this complex was 5.0 ppm), 1-ethynyl-1-cyclohexanol (used in the composition in such an amount that in terms of mass units the content of this component was 300 ppm), 118 parts by mass of titanium oxide having an average primary particle diameter of 0.2 μm (SX-3103 manufactured by Sakai Chemical Industry Co., Ltd.) and 213 parts by mass of a spherical silica having an average particle diameter of 15 μm (HS-202 manufactured by Nippon Steel & Sumikin Materials Co., Ltd. Micron Co.) were mixed so as to prepare a curable silicone composition having a viscosity of 190 Pa·s at 25° C.

It was understood that when this composition was heated for 10 minutes at 120° C., the composition gave a thermoplastic article which was a solid having an unmeasurable viscosity and a type D durometer hardness of 64 at 25° C. and which had a viscosity of 6,300 Pa·s at 100° C. The degree of conversion in the hydrosilylation reaction was 76%.

When heated at 150° C., the obtained thermoplastic article fluidized and then lost fluidity. A cured product obtained by heating the thermoplastic article for 1 hour at 150° C. was a solid having an unmeasurable viscosity at 300° C., had a type D durometer hardness of 88 at 25° C., had a bending strength of 28 MPa, had a total luminous reflectance of 94% and had a cured product linear expansion coefficient of 103 ppm/° C.

A transfer molding machine and the above-mentioned thermoplastic article were used to produce the optical semiconductor device illustrated in FIG. 1. A good molded product free of burrs and voids was obtained by integrating molding with a lead frame at 130° C.

### Practical Example 3

48.4 parts by mass of methylvinylphenylpolysiloxane represented by the average unit formula:

(MeViSiO_{2/2})_{0.25}(Ph₂SiO_{2/2})_{0.30}(PhSiO_{3/2})_{0.45}(HO_{1/2})_{0.02}

51.6 parts by mass of methylvinylphenylpolysiloxane represented by the average unit formula:

(Me₂ViSiO_{1/2})_{0.20}(PhSiO_{3/2})_{0.80}(HO_{1/2})_{0.01}

12.9 parts by mass of dimethylvinylsiloxy-terminated polymethylphenylsiloxane represented by the average formula:

ViMe₂SiO(MePhSiO)_{17.5}SiViMe₂

29.0 parts by mass of 1,1,5,5-tetramethyl-3,3-diphenyltrisiloxane represented by the formula:

(HMe₂SiO)₂SiPh₂

(in an amount such that provided 0.96 moles of silicon atom-bonded hydrogen atoms in this component per 1 mol of total vinyl groups in the above-mentioned methylvinylphenylpolysiloxanes and dimethylvinylsiloxy-terminated polymethylphenylsiloxane), 0.04 parts by mass of 1,3,5,7-tetramethyltetracyclosiloxane (in an amount that provided 0.0037 moles of silicon atom-bonded hydrogen atoms in this component per 1 mol of total vinyl groups in the above-mentioned methylvinylphenylpolysiloxanes and dimethylvinylsiloxy-terminated polymethylphenylsiloxane), a 1,3-divinyl-1,1,3,3-tetramethyldisiloxane solution of a platinum-1,3-divinyl-1,1,3,3-tetramethyldisiloxane complex (used in the composition in such an amount that in terms of mass units the content of the metallic platinum in this complex was 5.0 ppm), 1-ethynyl-1-cyclohexanol (used in the composition in such an amount that in terms of mass units the content of this component was 300 ppm), 118 parts by mass of titanium dioxide having an average primary particle diameter of 0.24 μm (Tipaque R-630 manufactured by Ishihara Sangyo Kaisha Ltd.) and 213 parts by mass of milled glass fibers having an average fiber diameter of 3 μm (MF03JB1-20 manufactured by Asahi Fiber Glass Co., Ltd.) were mixed so as to prepare a reactive silicone composition having a viscosity of 175 Pa·s of 25° C.

It was understood that when this composition was heated for 10 minutes at 120° C., the composition gave a thermoplastic article which was a solid having an unmeasurable viscosity and a type D durometer hardness of 72 at 25° C. and which had a viscosity of 21,000 Pa·s at 100° C. The degree of conversion in the hydrosilylation reaction was 89%.

When heated at 150° C., the obtained thermoplastic article fluidized and then lost fluidity. A cured product obtained by heating the thermoplastic article for 1 hour at 150° C. was a solid having no fluidity at a temperature of 300° C. or lower, had a type D durometer hardness of 86 at 25° C., had a bending strength of 21 MPa, had a total luminous reflectance of 95% and had a cured product linear expansion coefficient of 102 ppm/° C.

A transfer molding machine and the above-mentioned thermoplastic article were used to produce the optical semiconductor device illustrated in FIG. 1. A good molded product free of burrs and voids was obtained by integrating molding with a lead frame at 130° C.

### Practical Example 4

38.5 parts by mass of methylvinylphenylpolysiloxane represented by the average unit formula:

(MeViSiO_{2/2})_{0.25}(Ph₂SiO_{2/2})_{0.30}(PhSiO_{3/2})_{0.45}(HO_{1/2})_{0.02}

61.5 parts by mass of methylvinylphenylpolysiloxane represented by the average unit formula:

(Me₂ViSiO_{1/2})_{0.20}(PhSiO_{3/2})_{0.80}(HO_{1/2})_{0.01}

19.4 parts by mass of dimethylvinylsiloxy-terminated polymethylphenylsiloxane represented by the average formula:

ViMe₂SiO(MePhSiO)_{17.5}SiViMe₂

28.2 parts by mass of 1,1,5,5-tetramethyl-3,3-diphenyltrisiloxane represented by the formula:

(HMe₂SiO)₂SiPh₂

(in an amount that provided 0.96 moles of silicon atom-bonded hydrogen atoms in this component per 1 mol of total vinyl groups in the above-mentioned methylvinylphenylpolysiloxanes and dimethylvinylsiloxy-terminated polymethylphenylsiloxane), a 1,3-divinyl-1,1,3,3-tetramethyldisiloxane solution of a platinum-1,3-divinyl-1,1,3,3-tetramethyldisiloxane complex (used in the composition in such an amount that in terms of mass units the content of the metallic platinum in this complex was 5.0 ppm), 1-ethynyl-1-cyclohexanol (used in the composition in such an amount that in terms of mass units the content of this component was 300 ppm), 118 parts by mass of titanium oxide having an average primary particle diameter of 0.2 μm (SX-3103 manufactured by Sakai Chemical Industry Co., Ltd.) and 213 parts by mass of a crushed quartz powder having an average particle diameter of 5 μm (Silicic SAB-500 manufactured by Yamamori Tsuchimoto Mining Co., Ltd.) were mixed so as to prepare a reactive silicone composition having a viscosity of 455 Pa·s at 25° C.

It was understood that when this composition was heated for 10 minutes at 120° C., the composition gave a thermoplastic article which was a solid having an unmeasurable viscosity and a type D durometer hardness of 72 at 25° C. and which had a viscosity of 15,000 Pa·s at 100° C. The degree of conversion in the hydrosilylation reaction was 87%.

When heated at 150° C., the obtained thermoplastic article fluidized and then lost fluidity. A cured product obtained by heating the thermoplastic article for 1 hour at 150° C. was a solid having no fluidity at a temperature of 300° C. or lower, had a type D durometer hardness of 88 at 25° C., had a bending strength of 22 MPa, had a total luminous reflectance of 94% and had a cured product linear expansion coefficient of 117 ppm/° C.

A transfer molding machine and the above-mentioned thermoplastic article were used to produce the optical semiconductor device illustrated in FIG. 1. A good molded product free of burrs and voids was obtained by integrating molding with a lead frame at 130° C.

### Practical Example 5

38.5 parts by mass of methylvinylphenylpolysiloxane represented by the average unit formula:

(MeViSiO_{2/2})_{0.25}(Ph₂SiO_{2/2})_{0.30}(PhSiO_{3/2})_{0.45}(HO_{1/2})_{0.02}

61.5 parts by mass of methylvinylphenylpolysiloxane represented by the average unit formula:

(Me₂ViSiO_{1/2})_{0.20}(PhSiO_{3/2})_{0.80}(HO_{1/2})_{0.01}

25.6 parts by mass of dimethylvinylsiloxy-terminated polymethylphenylsiloxane represented by the average formula:

ViMe₂SiO(MePhSiO)_{17.5}SiViMe₂

28.2 parts by mass of 1,1,5,5-tetramethyl-3,3-diphenyltrisiloxane represented by the formula:

(HMe₂SiO)₂SiPh₂

(in an amount that provided 0.11 moles of silicon atom-bonded hydrogen atoms in this component per 1 mol of total vinyl groups in the above-mentioned methylvinylphenylpolysiloxanes and dimethylvinylsiloxy-terminated polymethylphenylsiloxane), a 1,3-divinyl-1,1,3,3-tetramethyldisiloxane solution of a platinum-1,3-divinyl-1,1,3,3-tetramethyldisiloxane complex (used in the composition in such an amount that in terms of mass units the content of the metallic platinum in this complex was 5.0 ppm), 1-ethynyl-1-cyclohexanol (used in the composition in such an amount that in terms of mass units the content of this component was 300 ppm), 128 parts by mass of titanium oxide having an average primary particle diameter of 0.2 μm (SX-3103 manufactured by Sakai Chemical Industry Co., Ltd.) and 256 parts by mass of a spherical silica having an average particle diameter of 15 μm (HS-202 manufactured by Nippon Steel & Sumikin Materials Co., Ltd. Micron Co.) were mixed so as to prepare a reactive silicone composition having a viscosity of 176 Pa·s at 25° C.

It was understood that when this composition was heated for 10 minutes at 120° C., the composition gave a thermoplastic article which was a solid having an unmeasurable viscosity and a type D durometer hardness of 74 at 25° C. and which had a viscosity of 8,600 Pa·s at 100° C. The degree of conversion in the hydrosilylation reaction was 76%.

When heated to 150° C., the obtained thermoplastic article fluidized and then lost fluidity. A cured product obtained by heating the thermoplastic article for 1 hour at 150° C. was a solid having no fluidity at a temperature of 300° C. or lower, had a type D durometer hardness of 87 at 25° C., had a bending strength of 22 MPa, had a total luminous reflectance of 94% and had a cured product linear expansion coefficient of 94 ppm/° C.

A transfer molding machine and the above-mentioned semi-cured product were used to produce the optical semiconductor device illustrated in FIG. 1. A good molded product free of burrs and voids was obtained by integrating molding with a lead frame at 130° C.

### Practical Example 6

38.5 parts by mass of methylvinylphenylpolysiloxane represented by the average unit formula:

(MeViSiO_{2/2})_{0.25}(Ph₂SiO_{2/2})_{0.30}(PhSiO_{3/2})_{0.45}(HO_{1/2})_{0.02}

61.5 parts by mass of methylvinylphenylpolysiloxane represented by the average unit formula:

(Me₂ViSiO_{1/2})_{0.20}(PhSiO_{3/2})_{0.80}(HO_{1/2})_{0.01}

25.6 parts by mass of dimethylvinylsiloxy-terminated polymethylphenylsiloxane represented by the average formula:

ViMe₂SiO(MePhSiO)_{17.5}SiViMe₂

28.2 parts by mass of 1,1,5,5-tetramethyl-3,3-diphenyltrisiloxane represented by the formula:

(HMe₂SiO)₂SiPh₂

(in an amount that provided 0.11 moles of silicon atom-bonded hydrogen atoms in this component per 1 mol of total vinyl groups in the above-mentioned methylvinylphenylpolysiloxanes and dimethylvinylsiloxy-terminated polymethylphenylsiloxane), a 1,3-divinyl-1,1,3,3-tetramethyldisiloxane solution of a platinum-1,3-divinyl-1,1,3,3-tetramethyldisiloxane complex (used in the composition in such an amount that in terms of mass units the content of the metallic platinum in this complex was 5.0 ppm), 1-ethynyl-1-cyclohexanol (used in the composition in such an amount that in terms of mass units the content of this component was 300 ppm), 141 parts by mass of titanium oxide having an average primary particle diameter of 0.2 μm (SX-3103 manufactured by Sakai Chemical Industry Co., Ltd.) and 282 parts by mass of milled glass fibers having an average cut length of 20 μm and an average fiber diameter of 3 (MF03JB1-20 manufactured by Asahi Fiber Glass Co., Ltd.) were mixed so as to prepare a reactive silicone composition having a viscosity of 380 Pa·s at 25° C.

It was understood that when this composition was heated for 10 minutes at 120° C., the composition gave a thermoplastic article which was a solid having an unmeasurable viscosity and a type D durometer hardness of 75 at 25° C. and which had a viscosity of 12,000 Pa·s at 100° C. The degree of conversion in the hydrosilylation reaction was 88%.

When heated to 150° C., the obtained thermoplastic article fluidized and then lost fluidity. A cured product obtained by heating the thermoplastic article for 1 hour at 150° C. was a solid having no fluidity at a temperature of 300° C. or lower, had a type D durometer hardness of 88 at 25° C., had a bending strength of 26 MPa, had a total luminous reflectance of 94% and had a cured product linear expansion coefficient of 65 ppm/° C.

A transfer molding machine and the above-mentioned semi-cured product were used to produce the optical semiconductor device illustrated in FIG. 1. A good molded product free of burrs and voids was obtained by integrating molding with a lead frame at 130° C.

### Comparative Example 1

100 parts by mass of methylvinylphenylpolysiloxane represented by the average unit formula:

(Me₂ViSiO_{1/2})_{0.20}(PhSiO_{3/2})_{0.80}(HO_{1/2})_{0.01}

12.5 parts by mass of dimethylvinylsiloxy-terminated polymethylphenylsiloxane represented by the average formula:

ViMe₂SiO(MePhSiO)_{17.5}SiViMe₂

25.0 parts by mass of the 1,1,5,5-tetramethyl-3,3-diphenyltrisiloxane represented by the formula:

(HMe₂SiO)₂SiPh₂

(in an amount that provided 0.79 moles of silicon atom-bonded hydrogen atoms in this component per 1 mol of total vinyl groups in the above-mentioned methylvinylphenylpolysiloxane and dimethylvinylsiloxy-terminated polymethylphenylsiloxane), a 1,3-divinyl-1,1,3,3-tetramethyldisiloxane solution of a platinum-1,3-divinyl-1,1,3,3-tetramethyldisiloxane complex (used in the composition in such an amount that in terms of mass units the content of the metallic platinum in this complex was 5.0 ppm), 1-ethynyl-1-cyclohexanol (used in the composition in such an amount that in terms of mass units the content of this component was 300 ppm), 115 parts by mass of titanium oxide having an average primary particle diameter of 0.2 μm (SX-3103 manufactured by Sakai Chemical Industry Co., Ltd.) and 206 parts by mass of a crushed quartz powder having an average particle diameter of 5 (Crystalite VX-52 manufactured by Tatsumori Ltd.) were mixed so as to prepare a reactive silicone composition having a viscosity of 422 Pa·s at 25° C.

It was understood that when this composition was heated for 10 minutes at 120° C., the composition gave a solid having an unmeasurable viscosity and a type D durometer hardness of 81 at 25° C., but gave a solid having an unmeasurable viscosity at 100° C., and did not give a thermoplastic article. The degree of conversion in the hydrosilylation reaction was 96%.

A transfer molding machine and the obtained solid were used to produce the optical semiconductor device illustrated in FIG. 1. When integrating molding was attempted with a lead frame at 130° C., the solid was hardly filled in the mold and a homogeneous molded article could not be obtained.

### Comparative Example 2

48.4 parts by mass of methylvinylphenylpolysiloxane represented by the average unit formula:

(MeViSiO_{2/2})_{0.25}(Ph₂SiO_{2/2})_{0.30}(PhSiO_{3/2})_{0.45}(HO_{1/2})_{0.02}

51.6 parts by mass of methylvinylphenylpolysiloxane represented by the average unit formula:

(Me₂ViSiO_{1/2})_{0.20}(PhSiO_{3/2})_{0.80}(HO_{1/2})_{0.01}

12.9 parts by mass of dimethylvinylsiloxy-terminated polymethylphenylsiloxane represented by the average formula:

ViMe₂SiO(MePhSiO)_{17.5}SiViMe₂

14.5 parts by mass of 1,1,5,5-tetramethyl-3,3-diphenyltrisiloxane represented by the formula:

(HMe₂SiO)₂SiPh₂

(in an amount that provided 0.48 moles of silicon atom-bonded hydrogen atoms in this component per 1 mol of total vinyl groups in the above-mentioned methylvinylphenylpolysiloxanes and dimethylvinylsiloxy-terminated polymethylphenylsiloxane), 14.5 parts by mass of silicon atom-bonded hydrogen atom-containing methylphenylpolysiloxane represented by the average unit formula:

(Me₂HSiO_{1/2})_{0.60}(SiO_{4/2})_{0.40}

(in an amount that provided 0.48 moles of silicon atom-bonded hydrogen atoms in this component per 1 mol of total vinyl groups in the above-mentioned methylvinylphenylpolysiloxanes and dimethylvinylsiloxy-terminated polymethylphenylsiloxane), a 1,3-divinyl-1,1,3,3-tetramethyldisiloxane solution of a platinum-1,3-divinyl-1,1,3,3-tetramethyldisiloxane complex (used in the composition in such an amount that in terms of mass units the content of the metallic platinum in this complex was 5.0 ppm), 1-ethynyl-1-cyclohexanol (used in the composition in such an amount that in terms of mass units the content of this component was 300 ppm), 118 parts by mass of titanium oxide having an average primary particle diameter of 0.2 μm (SX-3103 manufactured by Sakai Chemical Industry Co., Ltd.) and 213 parts by mass of a spherical silica having an average particle diameter of 15 μm (HS-202 manufactured by Nippon Steel & Sumikin Materials Co., Ltd. Micron Co.) were mixed so as to prepare a curable silicone composition having a viscosity of 592 Pa·s at 25° C.

It was understood that when this composition was heated for 10 minutes at 120° C., the composition gave a solid having an unmeasurable viscosity and a type D durometer hardness of 75 at 25° C., but gave a solid having an unmeasurable viscosity at 100° C., and did not give a thermoplastic article. The degree of conversion in the hydrosilylation reaction was 88%.

A transfer molding machine and the obtained solid were used to produce the optical semiconductor device illustrated in FIG. 1. When integrating molding was attempted with a lead frame at 130° C., the solid was hardly filled in the mold and a homogeneous molded article could not be obtained.

### Comparative Example 3

100 parts by mass of methylvinylphenylpolysiloxane represented by the average unit formula:

(MeViSiO_{2/2})_{0.20}(Me₂SiO_{2/2})_{0.20}(Ph₂SiO_{2/2})_{0.10}(PhSiO_{3/2})_{0.50}(HO_{1/2})_{0.03}

13.3 parts by mass of dimethylvinylsiloxy-terminated polymethylphenylsiloxane represented by the average formula:

ViMe₂SiO(MePhSiO)_{17.5}SiViMe₂

33.3 parts by mass of 1,1,5,5-tetramethyl-3,3-diphenyltrisiloxane represented by the formula:

(HMe₂SiO)₂SiPh₂

(in an amount that provided 1.10 moles of silicon atom-bonded hydrogen atoms in this component per 1 mol of total vinyl groups in the above-mentioned methylvinylphenylpolysiloxane and dimethylvinylsiloxy-terminated polymethylphenylsiloxane), a 1,3-divinyl-1,1,3,3-tetramethyldisiloxane solution of a platinum-1,3-divinyl-1,1,3,3-tetramethyldisiloxane complex (used in the composition in such an amount that in terms of mass units the content of the metallic platinum in this complex was 5.0 ppm), 1-ethynyl-1-cyclohexanol (used in the composition in such an amount that in terms of mass units the content of this component was 300 ppm), 122 parts by mass of titanium oxide having an average primary particle diameter of 0.2 μm (SX-3103 manufactured by Sakai Chemical Industry Co., Ltd.) and 220 parts by mass of milled glass fibers having an average cut length of 20 μm and an average fiber diameter of 3 μm (MF03JB1-20 manufactured by Asahi Fiber Glass Co., Ltd.) were mixed so as to prepare a reactive silicone composition having a viscosity of 186 Pa·s at 25° C.

It was understood that when this composition was heated for 10 minutes at 120° C., the heated composition had a viscosity of 21,000 Pa·s and a type D durometer hardness of 10 at 25° C., and did not give a thermoplastic article. The degree of conversion in the hydrosilylation reaction was 81%.

A transfer molding machine and the obtained liquid were used to produce the optical semiconductor device illustrated in FIG. 1. When integrating molding was attempted with a lead frame at 130° C., the liquid adhered strongly to the mold and the molded portion readily deformed.

### Comparative Example 4

100 parts by mass of methylvinylphenylpolysiloxane represented by the average unit formula:

(MeViSiO_{2/2})_{0.20}(Me₂SiO_{2/2})_{0.20}(Ph₂SiO_{2/2})_{0.10}(PhSiO_{3/2})_{0.50}(HO_{1/2})_{0.03}

13.3 parts by mass of dimethylvinylsiloxy-terminated polymethylphenylsiloxane represented by the average formula:

ViMe₂SiO(MePhSiO)_{17.5}SiViMe₂

30.0 parts by mass of 1,1,5,5-tetramethyl-3,3-diphenyltrisiloxane represented by the formula:

(HMe₂SiO)₂SiPh₂

(in an amount that provided 0.99 moles of silicon atom-bonded hydrogen atoms in this component per 1 mol of total vinyl groups in the above-mentioned methylvinylphenylpolysiloxane and dimethylvinylsiloxy-terminated polymethylphenylsiloxane), 3.3 parts by mass of silicon atom-bonded hydrogen atom-containing methylphenylpolysiloxane represented by the average unit formula:

(Me₂HSiO_{1/2})_{0.60}(SiO_{4/2})_{0.40}

(in an amount that provided 0.11 moles of silicon atom-bonded hydrogen atoms in this component per 1 mol of total vinyl groups in the above-mentioned methylvinylphenylpolysiloxane and dimethylvinylsiloxy-terminated polymethylphenylsiloxane), a 1,3-divinyl-1,1,3,3-tetramethyldisiloxane solution of a platinum-1,3-divinyl-1,1,3,3-tetramethyldisiloxane complex (used in the composition in such an amount that in terms of mass units the content of the metallic platinum in this complex was 5.0 ppm), 1-ethynyl-1-cyclohexanol (used in the composition in such an amount that in terms of mass units the content of this component was 300 ppm), 122 parts by mass of titanium oxide having an average primary particle diameter of 0.2 μm (SX-3103 manufactured by Sakai Chemical Industry Co., Ltd.) and 220 parts by mass of milled glass fibers having an average cut length of 20 μm and an average fiber diameter of 3 (MF03JB1-20 manufactured by Asahi Fiber Glass Co., Ltd.) were mixed so as to prepare a reactive silicone composition having a viscosity of 221 Pa·s at 25° C.

It was understood that when this composition was heated for 10 minutes at 120° C., the composition gave a solid having an unmeasurable viscosity and a type D durometer hardness of 60 at 25° C., but gave a solid having an unmeasurable viscosity at 100° C., and did not give a thermoplastic article. The degree of conversion in the hydrosilylation reaction was 78%.

A transfer molding machine and the obtained solid were used to produce the optical semiconductor device illustrated in FIG. 1. When integrating molding was attempted with a lead frame at 130° C., the solid filled the mold unsatisfactorily and a non-uniform molded article having many voids was obtained.

### Comparative Example 5

100 parts by mass of methylvinylphenylpolysiloxane represented by the average unit formula:

(MeViSiO_{2/2})_{0.25}(Ph₂SiO_{2/2})_{0.30}(PhSiO_{3/2})_{0.45}(HO_{1/2})_{0.02}

13.3 parts by mass of dimethylvinylsiloxy-terminated polymethylphenylsiloxane represented by the average formula:

ViMe₂SiO(MePhSiO)_{17.5}SiViMe₂

33.3 parts by mass of 1,1,5,5-tetramethyl-3,3-diphenyltrisiloxane represented by the formula:

(HMe₂SiO)₂SiPh₂

(in an amount that provided 1.15 moles of silicon atom-bonded hydrogen atoms in this component per 1 mol of total vinyl groups in the above-mentioned methylvinylphenylpolysiloxane and dimethylvinylsiloxy-terminated polymethylphenylsiloxane), a 1,3-divinyl-1,1,3,3-tetramethyldisiloxane solution of a platinum-1,3-divinyl-1,1,3,3-tetramethyldisiloxane complex (used in the composition in such an amount that in terms of mass units the content of the metallic platinum in this complex was 5.0 ppm), 1-ethynyl-1-cyclohexanol (used in the composition in such an amount that in terms of mass units the content of this component was 300 ppm), 65 parts by mass of titanium oxide having an average primary particle diameter of 0.2 μm (SX-3103 manufactured by Sakai Chemical Industry Co., Ltd.) and 285 parts by mass of a crushed quartz powder having an average particle diameter of 5 μm (Crystalite VX-52 manufactured by Tatsumori Ltd.) were mixed so as to prepare a reactive silicone composition having a viscosity of 290 Pa·s at 25° C.

It was understood that when this composition was heated for 10 minutes at 120° C., the composition gave a thermoplastic article which was a solid having an unmeasurable viscosity and a type D durometer hardness of 64 at 25° C. and which had a viscosity of 3,200 Pa·s at 100° C. The degree of conversion in the hydrosilylation reaction was 86%.

When heated at 150° C., the obtained thermoplastic article fluidized and then lost fluidity. A cured product obtained by heating the thermoplastic article for 1 hour at 150° C. had no fluidity at a temperature of 300° C. or lower, had a type D durometer hardness of 86 at 25° C., had a bending strength of 21 MPa, had a total luminous reflectance of 65% and had a cured product linear expansion coefficient of 93 ppm/° C.

A transfer molding machine and the above-mentioned thermoplastic article were used to produce the optical semiconductor device illustrated in FIG. 1. A good molded product free of burrs and voids was obtained by integrating molding with a lead frame at 130° C.

### Comparative Example 6

100 parts by mass of methylvinylphenylpolysiloxane represented by the average unit formula:

(MeViSiO_{2/2})_{0.25}(Ph₂SiO_{2/2})_{0.30}(PhSiO_{3/2})_{0.45}(HO_{1/2})_{0.02}

13.3 parts by mass of dimethylvinylsiloxy-terminated polymethylphenylsiloxane represented by the average formula:

ViMe₂SiO(MePhSiO)_{17.5}SiViMe₂

33.3 parts by mass of 1,1,5,5-tetramethyl-3,3-diphenyltrisiloxane represented by the formula:

(HMe₂SiO)₂SiPh₂

(in an amount that provided 1.15 moles of silicon atom-bonded hydrogen atoms in this component per 1 mol of total vinyl groups in the above-mentioned methylvinylphenylpolysiloxane and dimethylvinylsiloxy-terminated polymethylphenylsiloxane), a 1,3-divinyl-1,1,3,3-tetramethyldisiloxane solution of a platinum-1,3-divinyl-1,1,3,3-tetramethyldisiloxane complex (used in the composition in such an amount that in terms of mass units the content of the metallic platinum in this complex was 5.0 ppm), 1-ethynyl-1-cyclohexanol (used in the composition in such an amount that in terms of mass units the content of this component was 300 ppm), 224 parts by mass of titanium oxide having an average primary particle diameter of 0.2 μm (SX-3103 manufactured by Sakai Chemical Industry Co., Ltd.) and 117 parts by mass of a crushed quartz powder having an average particle diameter of 5 μm (Crystalite VX-52 manufactured by Tatsumori Ltd.) were mixed so as to prepare a reactive silicone composition having a viscosity of 1,200 Pa·s at 25° C.

It was understood that when this composition was heated for 10 minutes at 120° C., the composition gave a solid having an unmeasurable viscosity and a type D durometer hardness of 67 at 25° C., but had a high viscosity of 2,000,000 Pa·s at 100° C., and did not give a good thermoplastic article. The degree of conversion in the hydrosilylation reaction was 89%.

When heated at 150° C., the obtained solid fluidized and then lost fluidity. A cured product obtained by heating the solid for 1 hour at 150° C. had no fluidity at a temperature of 300° C. or lower, had a type D durometer hardness of 88 at 25° C., had a bending strength of 22 MPa, had a total luminous reflectance of 94% and had a cured product linear expansion coefficient of 130 ppm/° C.

A transfer molding machine and the above-mentioned solid were used to produce the optical semiconductor device illustrated in FIG. 1. When integrating molding was carried out with a lead frame at 130° C., a multiplicity of voids was generated and a good molded product was not obtained.

### Comparative Example 7

100 parts by mass of methylvinylphenylpolysiloxane represented by the average unit formula:

(MeViSiO_{2/2})_{0.25}(Ph₂SiO_{2/2})_{0.30}(PhSiO_{3/2})_{0.45}(HO_{1/2})_{0.02}

13.3 parts by mass of dimethylvinylsiloxy-terminated polymethylphenylsiloxane represented by the average formula:

ViMe₂SiO(MePhSiO)_{17.5}SiViMe₂

33.3 parts by mass of 1,1,5,5-tetramethyl-3,3-diphenyltrisiloxane represented by the formula:

(HMe₂SiO)₂SiPh₂

(in an amount that provided 1.15 moles of silicon atom-bonded hydrogen atoms in this component per 1 mol of total vinyl groups in the above-mentioned methylvinylphenylpolysiloxane and dimethylvinylsiloxy-terminated polymethylphenylsiloxane), a 1,3-divinyl-1,1,3,3-tetramethyldisiloxane solution of a platinum-1,3-divinyl-1,1,3,3-tetramethyldisiloxane complex (used in the composition in such an amount that in terms of mass units the content of the metallic platinum in this complex was 5.0 ppm), 1-ethynyl-1-cyclohexanol (used in the composition in such an amount that in terms of mass units the content of this component was 300 ppm), 102 parts by mass of titanium oxide having an average primary particle diameter of 0.2 μm (SX-3103 manufactured by Sakai Chemical Industry Co., Ltd.) and 510 parts by mass of a crushed quartz powder having an average particle diameter of 5 μm (Crystalite VX-52 manufactured by Tatsumori Ltd.) were mixed, thereby obtaining a powdered mixture.

It was understood that when this composition was heated for 10 minutes at 120° C., the composition gave a non-uniform solid having an unmeasurable viscosity at 25° C., gave a solid having an unmeasurable viscosity at 100° C., and did not give a thermoplastic article. The degree of conversion in the hydrosilylation reaction was 85%.

A transfer molding machine and the above-mentioned solid were used to produce the optical semiconductor device illustrated in FIG. 1. When integrating molding was carried out with a lead frame at 130° C., many unfilled mold sections were found and a good molded product was not obtained.

### INDUSTRIAL APPLICABILITY

The reactive silicone composition of the present invention is substantially a solid at an ordinary temperature and gives a reactive thermoplastic article that is fluidized at elevated temperatures, this reactive thermoplastic article is suitable for molding a cured product in a heated mold, and the obtained cured product exhibits little reduction in mechanical strength or discoloration caused by heat or light and exhibits high light reflectance, and is therefore suitable as a material for forming a white casing material for a light emitting diode.

### DESCRIPTION OF SYMBOLS

1 Optical semiconductor element
2 Lead frame
3 Lead frame
4, 4′ Bonding wire
5 Light reflection material
6 Sealing agent

1. A reactive silicone composition comprising:
(A) 100 parts by mass of an organopolysiloxane represented by the average unit formula:
(R¹₃SiO_{1/2})ₐ(R¹₂SiO_{2/2})_{b}(R¹SiO_{3/2})_{c}(SiO_{4/2})_{d}(R²O_{1/2})ₑ
wherein R¹ are the same or different and are phenyl groups, alkyl groups having from 1 to 6 carbons, or alkenyl groups having from 2 to 6 carbons, provided that from 55 to 80 mol % of all R¹ are phenyl groups and from 10 to 20 mol % of all R¹ are alkenyl groups; R² is a hydrogen atom or alkyl group having from 1 to 6 carbons; and a, b, c, d, and e are numbers that respectively satisfy: 0≦a≦0.30, 0.10≦b≦0.70, 0.35≦c≦0.85, 0≦d≦0.20, 0≦e≦0.10, and a+b+c+d=1;
(B) from 0 to 40 parts by mass of an organopolysiloxane represented by the general formula:
R³₃SiO(R³₂SiO)ₙSiR³₃
wherein R³ are the same or different and are phenyl groups, alkyl groups having from 1 to 6 carbon atoms, or alkenyl groups having from 2 to 6 carbon atoms, provided that from 30 to 70 mol % of all R³ are phenyl groups and at least one R³ is an alkenyl group; and n is an integer in a range from 10 to 100;
(C) an organopolysiloxane represented by the general formula:
HR⁴₂SiO(R⁴₂SiO)ₘSiR⁴₂H
wherein R⁴ are the same or different and are phenyl groups or alkyl groups having from 1 to 6 carbon atoms, provided that from 15 to 100 mol % of all R⁴ are phenyl groups; and m is an integer in a range from 1 to 10,
in an amount that provides from 0.5 to 2.5 moles of silicon atom-bonded hydrogen atoms in this component per 1 mol of total alkenyl groups in components (A) and (B);
(D) a hydrosilylation reaction catalyst in an amount sufficient to promote a hydrosilylation reaction between the alkenyl groups in components (A) and (B) and the silicon atom-bonded hydrogen atoms in component (C);
(E) a white pigment in an amount of at least 50 parts by mass per 100 parts by mass of the total amount of components (A) to (D); and
(F) non-spherical silica, spherical silica or glass fibers in an amount of at least 50 parts by mass per 100 parts by mass of the total amount of components (A) to (D);
the total content of components (E) and (F) being not more than 400 parts by mass per 100 parts by mass of the total amount of components (A) to (D).

2. The reactive silicone composition according to claim 1, further comprising: (G) an organopolysiloxane represented by the average unit formula:
(R⁵₃SiO_{1/2})_{f}(R⁵₂SiO_{2/2})_{g}(R⁵SiO_{3/2})ₕ(SiO_{4/2})ᵢ(R⁶O_{1/2})ⱼ
wherein R⁵ are the same or different and are phenyl groups, alkyl groups having from 1 to 6 carbon atoms, alkenyl groups having from 2 to 6 carbon atoms, or epoxy group-containing organic groups, provided that from 15 to 60 mol % of all R⁵ are phenyl groups, from 3 to 30 mol % of all R⁵ are alkenyl groups, and from 5 to 30 mol % of all R⁵ are epoxy group-containing organic groups; R⁶ is a hydrogen atom or an alkyl group having from 1 to 6 carbon atoms; and, f, g, h, i, and j are numbers that respectively satisfy: 0≦f≦0.5, 0≦g≦0.9, 0≦h≦0.7, 0≦i≦0.3, 0≦j≦0.02, and f+g+h+i=1, in an amount of from 0.5 to 10.0 parts by mass per 100 parts by mass of the total amount of components (A) to (D).

3. The reactive silicone composition according to claim 1, further comprising: (H) an organopolysiloxane having at least two silicon atom-bonded hydrogen atoms in a molecule and in which the content of phenyl groups relative to all of the silicon atom-bonded organic groups is less than 20 mol %, in an amount that provides from 0.001 to 0.20 moles of silicon atom-bonded hydrogen atoms in this component per 1 mol of total alkenyl groups in components (A) and (B).

4. The reactive silicone composition according to claim 1, wherein the composition has a viscosity of not more than 1,000 Pa·s at 25° C.

5. A reactive thermoplastic article obtained by subjecting the reactive silicone composition according to claim 1 to hydrosilylation reaction until the degree of conversion is from 70 to 95%.

6. The reactive thermoplastic article according to claim 5, which is a solid or a liquid with a viscosity of at least 1,000,000 Pa·s at 25° C., and is a liquid with a viscosity of not more than 100,000 Pa·s at 100° C.

7. The reactive thermoplastic article according to claim 5, wherein a type D durometer hardness, as stipulated in JIS K 7215, is at least 30 at 25° C.

8. The reactive thermoplastic article according to claim 5, which forms a cured product that does not display flowability at temperatures of 300° C. or lower when heated at a temperature of 100° C. or higher.

9. A cured product which is a solid or a liquid having a viscosity with at least 1,000,000 Pa·s at 300° C., obtained by heating the reactive thermoplastic article according to claim 5 at a temperature of 100° C. or higher.

10. The cured product according to claim 9, wherein the cured product has a total luminous reflectance of at least 80%.

11. The cured product according to claim 9, wherein the cured product has an average coefficient of linear expansion of not more than 200 ppm/° C. within a temperature range of from 25 to 200° C.

12. An optical semiconductor device comprising a light reflection material formed from the cured product according to claim 9.

13. The reactive silicone composition according to claim 2, further comprising: (H) an organopolysiloxane having at least two silicon atom-bonded hydrogen atoms in a molecule and in which the content of phenyl groups relative to all of the silicon atom-bonded organic groups is less than 20 mol %, in an amount that provides from 0.001 to 0.20 moles of silicon atom-bonded hydrogen atoms in this component per 1 mol of total alkenyl groups in components (A) and (B).

14. The reactive thermoplastic article according to claim 6, wherein a type D durometer hardness, as stipulated in JIS K 7215, is at least 30 at 25° C.
